(19) United States
(12) Patent Application Publication
(10) Pub. No.: US 2020/0235608 A1
(43) Pub. Date: Jul. 23, 2020

(54) Sensor Network Node System With Energy Harvesting Pickup/Receiver

(71) Applicant: MH ELECTRIC MOTOR & CONTROL CORP., Marrenville, IL (US)

(72) Inventors: Phillip J. LaFayette, Carol Stream, IL (US); Michael H. Holz, Downers Grove, IL (US)

(21) Appl. No.: 16/840,356

(22) Filed: Apr. 4, 2020

Related U.S. Application Data
(63) Continuation of application No. PCT/US18/55952, filed on Oct. 15, 2018.
(60) Provisional application No. 62/573,072, filed on Oct. 16, 2017.

(51) Int. Cl. H02J 50/00; H02J 50/10; H02K 11/00; H02K 11/20; H05K 1/18

(52) U.S. Cl. CPC H02J 50/001; H02J 50/10; H02K 11/0094; H02K 11/20; H05K 1/181; H04B 1/40; H05K 2201/1003; H05K 2201/10037; H05K 2201/10098; H05K 2201/10522; H05K 2201/10151

(57) ABSTRACT

A system node can include a printed circuit board with an electronic processor, a sensor module residing on the printed circuit board, and an energy harvesting module comprising an energy harvesting pickup/receiver capable of harvesting electromagnetic energy. The sensor module is capable of detecting one or more detectable phenomenon from the surrounding environment and generating electrical signals corresponding to the detectable phenomenon. The system node can include an energy storage device and a wireless transceiver module. The detectable phenomenon can include at least one of the following: light levels, voltage, current, pH, temperature, barometric pressure, material stress, material strain, vibration in time-domain, vibration in frequency domain, humidity, electrical phase-relationships, seismic activity, and fluid flow. The detectable phenomenon can be generated by a dynamic device, such as, but not limited to, a vehicle, a fluid-carrying pipe, a motor, structure, and/or a building having swaying properties.

### CROSS-REFERENCE TO RELATED APPLICATION

This application is a continuation of and claims priority to international application No PCT/US18/55952, filed on Oct. 15, 2018 entitled, “Sensor Network Node with Energy Harvesting Pickup/Receiver”. The '952 application claims priority benefits from U.S. provisional patent application Ser. No. 62/573,072 filed on Oct. 16, 2017 also entitled, “Sensor Network Node with Energy Harvesting Pickup/Receiver”. The '952 and '072 applications are hereby incorporated by reference herein in their entireties.

### FIELD OF THE INVENTION

The present application relates to sensors and, in particular, to a low power, energy harvesting, modular, wireless sensor network node and energy harvesting pickup/receiver.

In this application, the term “network” means (a) any preexisting connection to the Internet, or (b) in the case where an existing connection is not feasible, the network is a connection consisting of a wired or wireless gateway and a global system for mobile communications (GSM; cellular based) access point. A network could also be a Local-Area Network (LAN) based Intranet, where no connection to the Internet would be required. Such a configuration would be suited to highly security-minded users, since the entire system could conceivably operate disconnected from the Internet at-large, with all communications remaining local to the premises.

In this application, the term “node” means any point in the system that can connect to other devices to exchange data, by generating data and/or receiving data. A “system node” has all components necessary for the exchange of data, wired or wireless communication. A system node is essentially an all-inclusive computing endpoint. A “sensor node” is a printed circuit board module or expansion board or daughterboard that contains one or more sensors. In at least some embodiments, each sensor node has basic data processing capabilities to carry out its detection functions. In some embodiments, each sensor node has the ability to communicate wirelessly. The phenomena capable of being detected by a sensor node comprise perceivable stimuli, including light levels, voltage, current, vibration in time-domain, vibration in frequency domain, humidity, electrical phase-relationships, temperature, gaseous/liquid flow, and other phenomena that can be communicated electronically.

In this application, the term “energy harvesting pickup/receiver” means a device that receives electromagnetic waves oriented perpendicularly to its conductor. The resulting electrical current is fed to a high-efficiency energy harvesting integrated circuit, and this conditioned current is then either fed to a rechargeable battery or the system node power supply. If fed to an operational amplifier, the resultant signal can be monitored, thereby effectively transforming the energy harvesting pickup/receiver into a sensor.

The sensor network node described herein is implemented on a printed circuit board (PCB) and comprises a number of integrated circuits and electronic components to facilitate the handling of data from sensors, the wireless transfer of that data to external recipients, and the harvesting of electrical energy. A central processing unit on the PCB directs and instructs the other components of the sensor system to perform their respective functions.

The low power aspect of the present system is closely related to the sensor network node system's harvesting of electrical energy, in that there is a balance between the amount of time the system can be “on” or active, versus the amount of time required to harvest sufficient energy to replenish the amount of battery life spent during that “on” time. Software and physical electronic components both serve to maintain this balance by cycling the sensor node system's power, switching subsystems as needed, and entering the lowest power consumption state, namely “hibernation”. It is desirable to include a removable memory device onboard the system, to allow data to be taken and locally stored over multiple periods of time without transmitting that data wirelessly; as wireless transmission of data is typically power intensive.

Electrical engineers have long sought to employ harvestable sources of energy while minimizing the limiting aspects associated with each. There are several known methods for harvesting electrical energy, with the three principal methods being thermoelectric, piezoelectric and solar. Each of the three harvestable sources of energy have significant limiting aspects before they can be considered viable: solar energy generation requires sunlight, thermoelectric energy generation requires steep temperature gradients, and piezoelectric energy generation requires vibrations of substantial magnitude. The present system and method avoids the limiting aspects of these three known harvestable sources of energy. In the present system, energy is harvested from a single or a plurality of alternating current carrying conductors with inductive coupling.

The present system employs an efficient energy harvesting integrated circuit to condition and store harvested electrical energy from an inductive pickup or receiver. The harvested energy is used to recharge a battery and/or power the entire system. In order to harvest energy from a source, the IC requires a connection to that source. To facilitate such a connection, a conductor is wound around either a dielectric material, or a magnetic flux carrying material or core. The winding can consist of an arbitrary number of turns and winding geometries. In general, the more turns the pickup/receiver has, the greater the magnitude of the voltage induced in the pickup/receiver conductor. According to Ampere's Law, an alternating current through a conductor of electric charge creates an oscillating magnetic field, at angles perpendicular to the direction of the current's flow. According to Faraday's Law of Induction, if the magnetic component of that field passes through another conductor of electric charge (namely, the inductive pickup or receiver), an alternating electromotive force (voltage) is induced. An alternating current in the inductive pickup/receiver is thereby created.

Proper balancing of the production and consumption of energy by the system is important, since the wireless transmission of information often requires high current to produce the transmission. Ordinarily, the potential energy able to be harvested through inductive coupling is small compared to the three other principal harvesting sources mentioned above (thermoelectric, piezoelectric, and solar). By virtue of the present system's intrinsic ability to affect this balance, inductive coupling becomes a viable and practical source for energy harvesting. Inductive coupling has a number of advantages in this regard, namely, by not requiring the presence of sunlight (solar), temperature differences (thermoelectric), or vibrations (piezoelectric). Existing inductive energy harvesting techniques can mostly employ an alternating current conductor as an energy source, in the form of a coil with a number of turns. In the present system, such an arrangement is unnecessary; so long as the pickup/receiver is wound beyond a certain minimal number of turns, is in close-enough proximity to the energy source, and the source carries a large enough alternating current or magnetic field, the energy source can be a single, unwound conductor that is distinguished from a coil.

### SUMMARY OF THE INVENTION

A system node can include:
(a) a printed circuit board comprising an electronic processor;
(b) a sensor module residing on the printed circuit board, the sensor module capable of detecting at least one detectable phenomenon from the surrounding environment and generating electrical signals corresponding to at least one detectable phenomenon; and
(c) an energy harvesting module comprising an energy harvesting pickup/receiver capable of harvesting electromagnetic energy.

In some embodiments, the energy harvesting module resides on the printed circuit board.

In some embodiments, the system node can include an energy storage device attachable to the printed circuit board.

In some embodiments, the system node can include a wireless transceiver module.

In some embodiments of the system node, the detectable phenomenon can include at least one of the following: light levels, voltage, current, pH, temperature, barometric pressure, material stress, material strain, vibration in time-domain, vibration in frequency domain, humidity, electrical phase-relationships, seismic activity, and fluid flow.

In some embodiments of the system node, the detectable phenomenon can be generated by a dynamic device. The dynamic device can include a vehicle, a fluid-carrying pipe, a motor, or a building or structure having swaying properties.

In some embodiments, the energy harvesting pickup/receiver can be a pickup coil in close proximity to at least one alternating electrical current source. The coil can be contoured to the source of electromagnetic energy.

In some embodiments, the energy harvesting pickup/receiver can be a pickup coil in close proximity to a fluctuating magnetic field produced from an outside source.

### BRIEF DESCRIPTION OF THE DRAWINGS

FIG. 1A is a perspective view of an embodiment of a printed circuit board of a low power, energy harvesting, modular, wireless sensor network node with energy harvesting pickup/receiver.

FIG. 1B is a top view an embodiment of a printed circuit board of a low power, energy harvesting, modular, wireless sensor network node with energy harvesting pickup/receiver.

FIG. 1C is a perspective view of the underside of the printed circuit board illustrated in FIGS. 1A and 1B.

FIG. 1D is a bottom view of the underside of the printed circuit board illustrated in FIGS. 1A and 1B.

FIG. 2A is a top view of an embodiment of an Energy Harvesting Module of a low power, energy harvesting, modular, wireless sensor network node and energy harvesting pickup/receiver.

FIG. 2B is a perspective view of an embodiment of an Energy Harvesting Module of a low power, energy harvesting, modular, wireless sensor network node and energy harvesting pickup/receiver.

FIG. 2C is a bottom view of the underside of the Energy Harvesting Module illustrated in FIGS. 2A and 2B.

FIG. 2D is a perspective view of the underside of the Energy Harvesting Module illustrated in FIGS. 2A and 2B.

FIG. 3A is a side elevation view of one embodiment of an Energy Harvesting Pickup/Receiver.

FIG. 3B is a side view of another embodiment of an Energy Harvesting Pickup/Receiver.

FIG. 3C is a perspective view of another embodiment of an Energy Harvesting Pickup/Receiver.

FIG. 3D is a schematic showing magnetic field lines impinging upon the Energy Harvesting Pickup/Receiver of FIG. 3A

FIG. 4A is a top view of another embodiment of an Energy Harvesting Pickup/Receiver.

FIG. 4B is a first perspective view of the Energy Harvesting Pickup/Receiver of FIG. 4A.

FIG. 4C is a second perspective view of the Energy Harvesting Pickup/Receiver of FIG. 4A.

FIG. 5A is a top view of another embodiment of an Energy Harvesting Pickup/Receiver.

FIG. 5B is first perspective view of the Energy Harvesting Pickup/Receiver of FIG. 5A.

FIG. 5C is a second perspective view of the Energy Harvesting Pickup/Receiver of FIG. 5A.

FIG. 5D is a third perspective view of the Energy Harvesting Pickup/Receiver of FIG. 5A.

FIG. 6A is a top view of an embodiment of a Wireless Transceiver Module associated with a low power, energy harvesting, modular, wireless sensor network node with energy harvesting pickup/receiver.

FIG. 6B is a top perspective view of the Wireless Transceiver Module of FIG. 6A.

FIG. 6C is a bottom view of the Wireless Transceiver Module of FIG. 6A.

FIG. 6D is a bottom perspective view of the Wireless Transceiver Module of FIG. 6A.

FIG. 7 is a perspective view showing a Wireless Transceiver Module being inserted into a printed circuit board for an embodiment of a present low power, energy harvesting, modular, wireless sensor network node with energy harvesting pickup/receiver illustrated in FIGS. 1A-1D.

FIG. 8 is a schematic showing the transmission of wireless signals from a Wireless Transceiver Module to one or more of devices capable of receiving the wireless signals.

FIG. 9 is perspective view of one embodiment of an Energy Storage Device associated with a low power, energy harvesting, modular, wireless sensor network node with energy harvesting pickup/receiver.

FIG. 10 is a perspective view of the Energy Storage Device partially shown in FIG. 9.

### DETAILED DESCRIPTION OF ILLUSTRATIVE EMBODIMENTS

The accompanying figures illustrate a low power, energy harvesting, modular, wireless sensor network node and affiliated energy harvesting pickup/receiver. The system can include a System Node 10, an Energy Harvesting Module 20, an Energy Harvesting Pickup/Receiver 30, a Wireless Transceiver Module 50, and an Energy Storage Device 80.

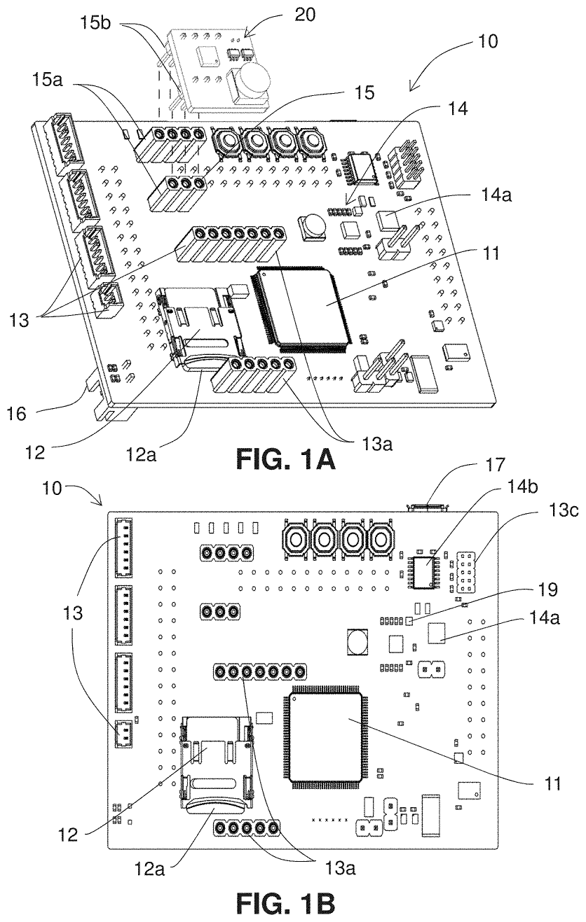

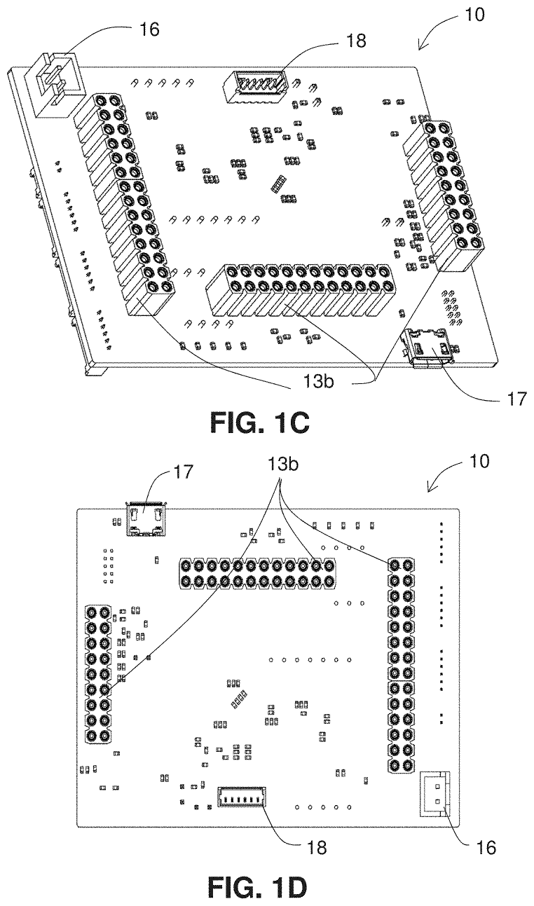

As first shown in FIGS. 1A-1D, System Node 10 can include an electronic printed circuit board, electronic processor 11, removable memory storage device 12, external connection sockets 13, electronic subsystems 14, Energy Harvesting Module connections 15, energy storage device connection 16, system connection 17, Ethernet expansion connection 18, and electronic subsystem switch 19.

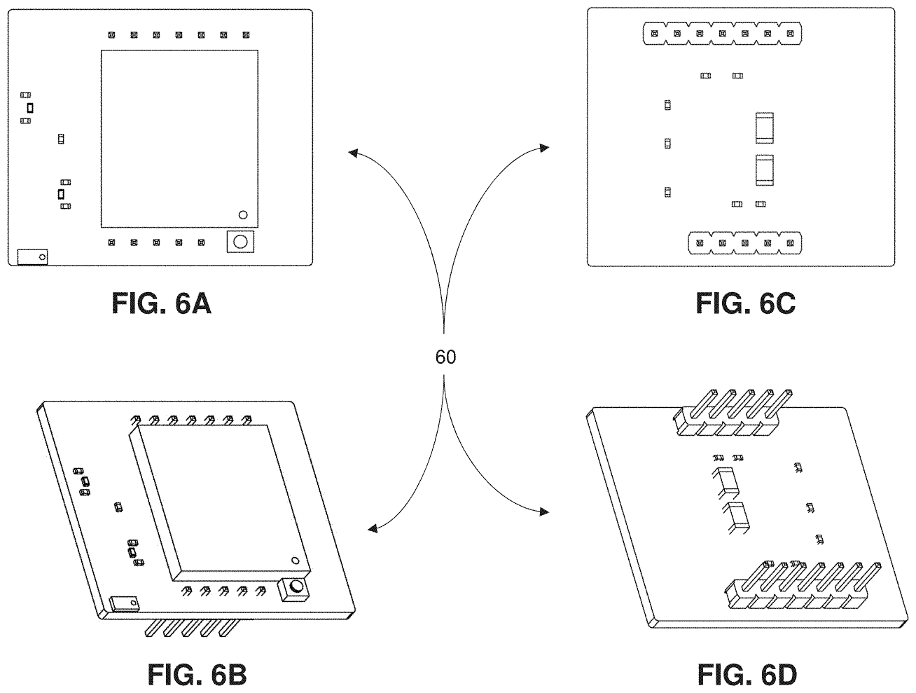

In some preferred embodiments, removable memory storage device 12 can be employed to implement a store-and-forward type of data handling, where data is taken from electronic sensors, processed by electronic processor 11, stored on removable media 12a, directed through external wireless module expansion connection 13a, and forwarded to a computer, tablet/mobile device, gateway, or another system node by a Wireless Transceiver Module (described below with respect to FIGS. 6A-6D, 7 and 8).

In some or the same preferred embodiments, external connection sockets 13 can be attached to sensors, devices, expansion boards, and/or other devices not already included on system node 10. Expansion board connection sockets 13b can be attached to one or more system node expansion boards. In some preferred embodiments, programming connection 13c can include an electrical connector. In some or the same preferred embodiments, programming connection 13c can be attached to electronic processor 11 and/or an external programming device, thereby allowing the transmission of data, software, commands, and/or instructions.

Electronic subsystems, the location of which are generally depicted by the arrow extending from numeral 14 (FIG. 1A), can include one or more onboard electronic circuits, integrated circuits, switches, digital sensors, analog sensors, amplifiers, signal conditioners, analog-to-digital converters, digital-to-analog converters, power controllers, voltage converters, voltage references, integrated memory components, resistors, capacitors, inductors, diodes, function generators, pulse-width modulators, digital signal processors, charge pumps, and/or other electrically connectable device(s).

In some embodiments, energy harvesting connections 15 can include electrical connections 15a and electrical connections 15b. Electrical connections 15a can include an electrical connector or connectors of either male or female type attached to electrical connections 15b. Electrical connections 15b can include an electrical connector or connectors of either male or female type, the opposite gender of 15a.

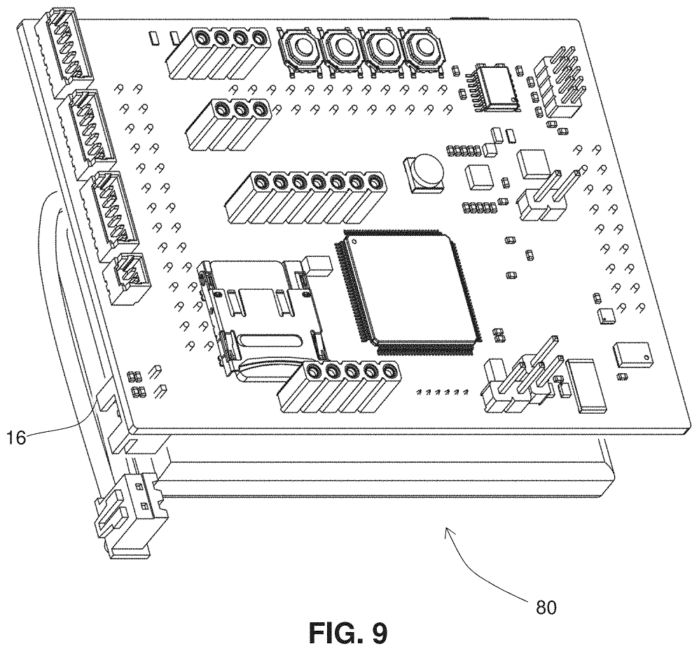

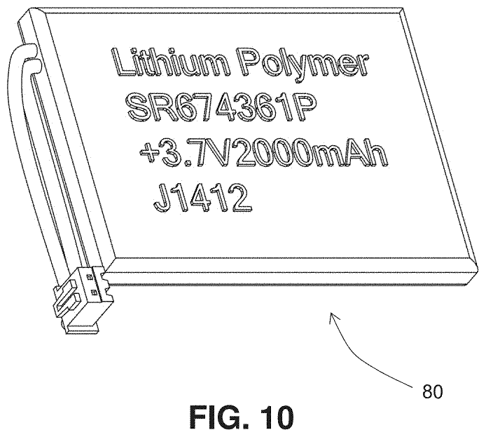

In some preferred embodiments, Energy Storage Device connection 16 can include an electrical connector. In some embodiments, Energy Storage Device connection 16 can be attached to an Energy Storage Device 80 (illustrated in FIGS. 9 and 10). In some embodiments, Energy Storage Device 80 can include a rechargeable type of cell or battery of cells.

System connection 17 can include an electrical connector. In some preferred embodiments, system connection 17 can be attached to an external cord, wire, conductor, cable, or cable assembly. System connection 17 can interface with Energy Storage Device charger module 14a and system terminal module 14b. System terminal module 14b can interface with electronic processor 11, thereby allowing access to an external data console or terminal for sending and receiving data, instructions, commands, and/or firmware.

Ethernet expansion connection 18 can include an electrical connector. In some preferred embodiments, ethernet expansion connection 18 can be attached to an external printed circuit board with a cable assembly. In some embodiments, the external printed circuit board can include the necessary electronics and electrical components to allow communication over Ethernet type cables.

Electronic subsystem switch 19 can include an electronic component switch and be connected to electronic processor 11, Energy Storage Device 80, and electronic subsystems 14. In some preferred embodiments, electronic subsystem switch 19 can be attached to electronic processor 11 to receive a signal or signals from electronic processor 11, the signal or signals directing the switching of power between Energy Storage Device 80 and electronic subsystems 14. In some of these embodiments, this arrangement can prevent, or reduce, unneeded or unwanted electrical energy from being drained from Energy Storage Device 80 by electronic subsystems 14.

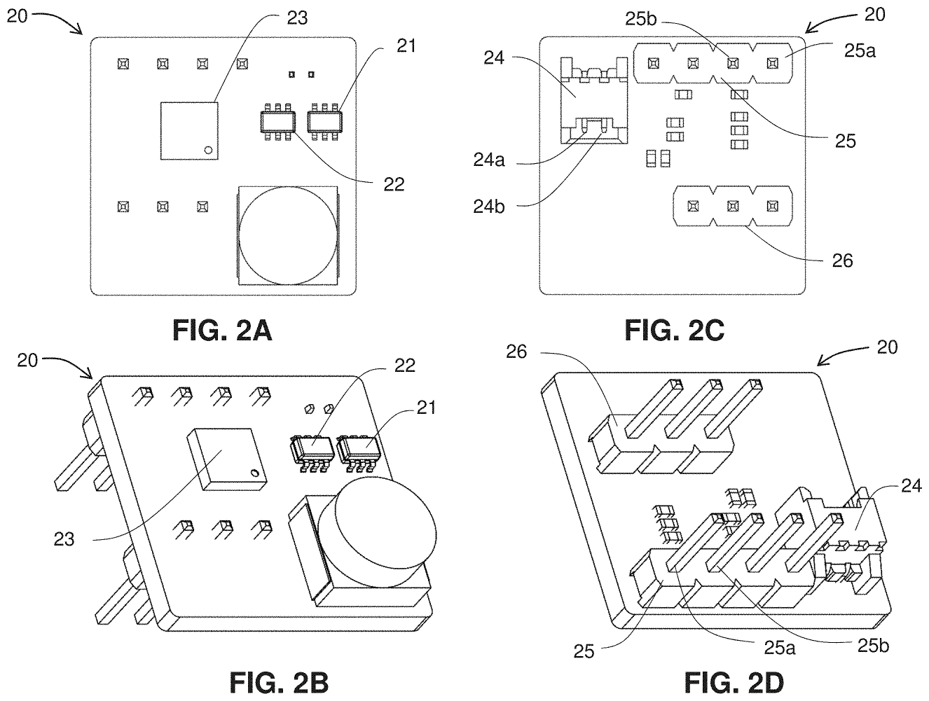

As shown in FIGS. 2A-2D, Energy Harvesting Module 20 can include an electronic printed circuit board. In some embodiments, Energy Harvesting Module 20 can be configured to integrate directly onto System Node 10. Other configurations are also possible. In some preferred embodiments, Energy Harvesting Module 20 can include electrical rectification circuitry 21, electrical amplification circuitry 22, electrical energy harvesting circuitry 23, energy harvesting pickup/receiver connection 24, electrical amplification circuitry connection 25, and/or energy harvesting output connection 26.

In some embodiments, electrical rectification circuitry 21 can include any electrical component configuration which can rectify an alternating electrical current from energy harvesting pickup/receiver connection 24 into a direct current form to be supplied to electrical energy harvesting circuitry 23. This arrangement includes, but is not limited to, diodes, half-bridge rectifiers, fullbridge rectifiers, and/or integrated rectification components.

In some embodiments, electrical amplification circuitry 22 can include electrical component configurations that can amplify an electrical current harvested from energy harvesting pickup/receiver connection 24 and be attached to electrical amplification circuitry connection 25. These components include, but are not limited to, transistors, instrumentation amplifiers, operational amplifiers, and/or integrated amplification components.

In some preferred embodiments, electrical amplification circuitry connection 25 can be attached to an electronics processor, thereby allowing Energy Harvesting Module 20 to perform additional functions as an electrical sensor.

Electrical energy harvesting circuitry 23 can include any electrical component configuration which can harvest electrical energy from the environment. In some preferred embodiments, electrical energy harvesting circuitry 23 can be connected to energy harvesting pickup/receiver connection 24, the harvested energy preferably stored in Energy Storage Device 80 (illustrated in FIGS. 9 and 10), via energy harvesting output connection 26. Electrical energy harvesting circuitry 23 can include other configurations, such as, but not limited to, removing energy harvesting output connection 26 and connecting electrical energy harvesting circuitry 23 directly to Energy Storage Device 80. In these embodiments, Energy Harvesting Module 20 can be integrated directly onto System Node 10.

Energy harvesting pickup/receiver connection 24 can include an electrical connector or connectors, preferably including pickup/receiver connections 24a and 24b. In some preferred embodiments, pickup/receiver connections 24a and 24b can include an electrical connector of either male or female type and be attached to pickup/receiver conductor connections 31a and 31b.

Electrical amplification circuitry connection 25 can include an electrical connector, preferably including amplifier connections 25a and 25b. In some preferred embodiments, electrical amplification circuitry connection 25 can be attached to electrical amplification circuitry 22 and electronics processor 11, thereby allowing electronics processor 11 to employ Energy Harvesting Module 20 as an electrical sensor.

Energy harvesting output connection 26 can include an electrical connector. In some preferred embodiments, energy harvesting output connection 26 can be attached to electrical energy harvesting circuitry 23 and Energy Storage Device 80. In some embodiments, electrical energy harvesting circuitry 23 can include other configurations, such as, but not limited to, removing energy harvesting output connection 26 and connecting electrical energy harvesting circuitry 23 directly to Energy Storage Device 80.

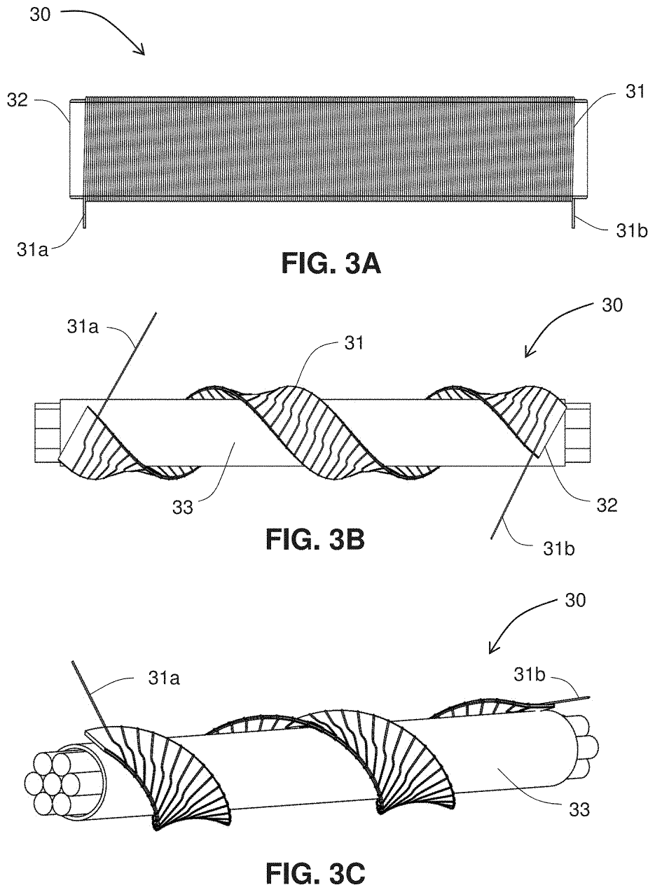

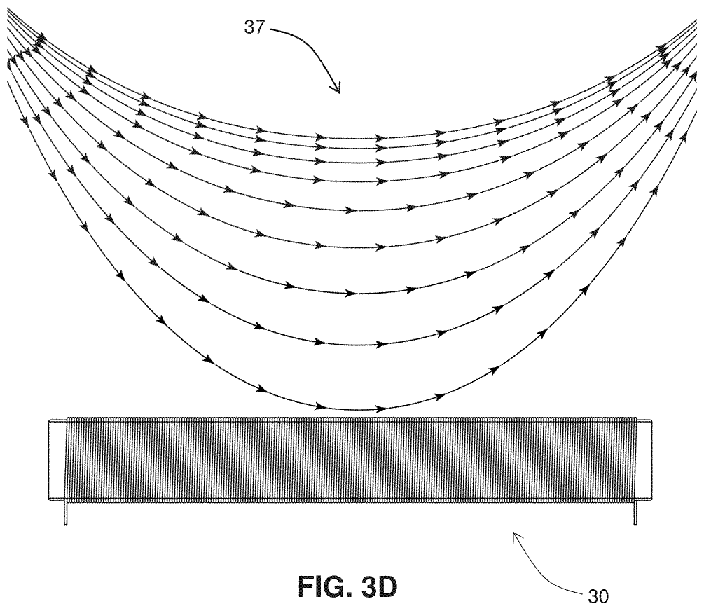

As shown in FIGS. 3A-3C, Energy Harvesting Pickup/Receiver 30 can include an electrical conductor 31, pickup/receiver conductor connections 31a and 31b, and a dielectric 32.

Electrical conductor 31 can include a material conducive to the conduction of electrons and/or electricity. In some preferred embodiments, electrical conductor 31 can include pickup/receiver conductor connections 31a and 31b. In some or the same preferred embodiments, electrical conductor 31 can be wound into a coil geometry around dielectric 32. Electrical conductor 31 can be other configurations, such as, but not limited to, alternate winding geometries or patterns.

In some embodiments, dielectric 32 can include a material that is not conducive to the conduction of electrons and/or electricity, and which acts as an insulator to electrical energy. In some embodiments, instead of dielectric 32, a flexible, magnetic material can be employed to facilitate the inductive coupling of pickup/receiver 30.

An alternate configuration of the Energy Harvesting Pickup/Receiver is shown in FIGS. 3B and 3C. Electrical conductor 41 can be placed around conductor 43. Electrical conductor 41 can include pickup/receiver conductor connections 31a and 31b. Dielectric 32 can include a material that is not conducive to the conduction of electrons and/or electricity, and which acts as an insulator to electrical energy. In some embodiments, instead of dielectric 32, a flexible, magnetic material can be employed to facilitate the inductive coupling of pickup/receiver 30.

An alternating current through conductor 33 creates an oscillating magnetic field at right angles to the direction of current flow, according to Ampere's Law. The magnetic component of the field passes through the Energy Harvesting Pickup/Receiver 30, where it induces an alternating electromotive force, according to Faraday's Law of Induction, thereby creating an alternating current in the Energy Harvesting Pickup/Receiver 30.

Another configuration of the Energy Harvesting Pickup/Receiver is shown in FIG. 3D. Energy Harvesting Pickup/Receiver 30 can be placed in close proximity to any oscillating magnetic field 37. Following Ampere's and Faraday's laws, the magnetic component of the field passes through Energy Harvesting Pickup/Receiver 30, thereby inducing an alternating electromotive force, which creates an alternating current in the Energy Harvesting Pickup/Receiver 30.

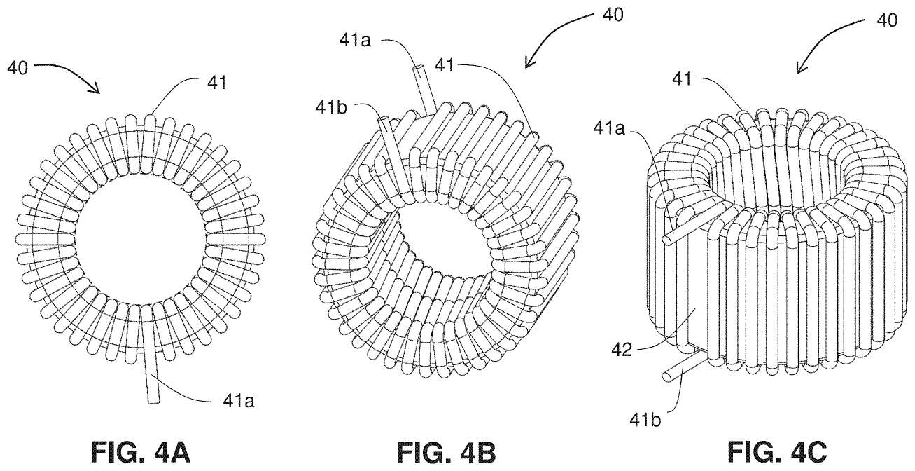

FIGS. 4A-4C depict yet another embodiment of an Energy Harvesting Pickup/Receiver. Energy Harvesting Pickup/Receiver 40 can include an electrical conductor 41, pickup/receiver conductor connections 41a and 41b, and closed magnetic toroid 42. This embodiment is just one example of the different geometries an Energy Harvesting Pickup/Receiver can employ.

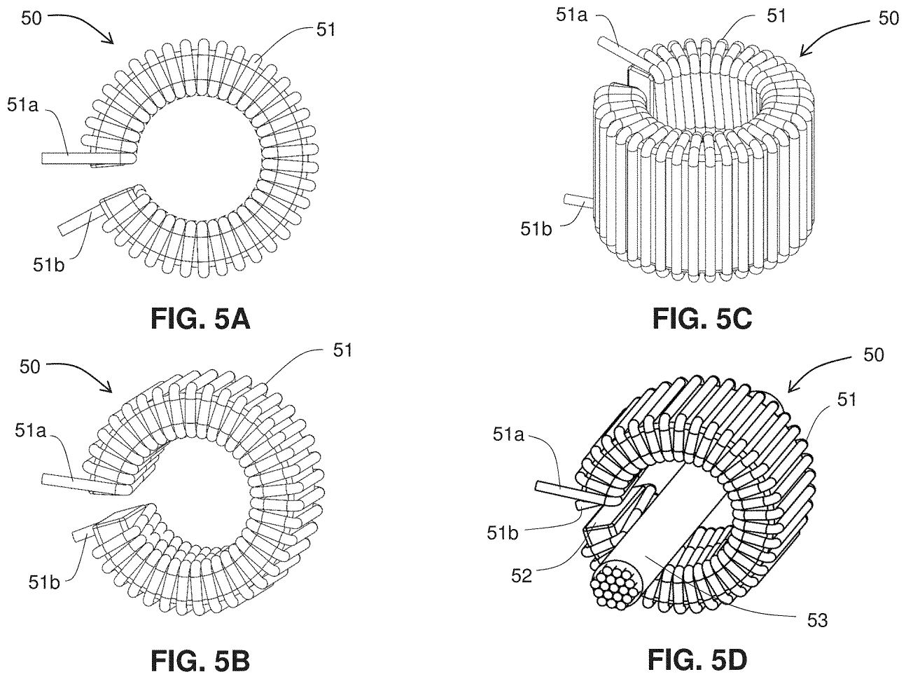

FIGS. 5A-5D depict yet another embodiment of an Energy Harvesting Pickup/Receiver. Energy Harvesting Pickup/Receiver 50 can include an electrical conductor 51, pickup/receiver conductor connections 51a and 51b, and flexible toroid core 52. This embodiment is another example of the different geometries an Energy Harvesting Pickup/Receiver can employ. In some preferred embodiments, flexible toroid core 52 can include an opening, to easily allow coupling with conductor 53 (shown in FIG. 5D). Conductor 53 is not shown in FIGS. 5A-5C for visual clarity. As shown in FIG. 5D, conductor 53 can be extended through the center of Energy Harvesting Pickup/Receiver 50 to allow a close proximity between conductor 53 and electrical conductor 51. When an alternating electrical current flows through conductor 53, an alternating magnetic field is created along the axis of conductor 53. When this magnetic field crosses electrical conductor 51, an alternating electrical force is produced in electrical conductor 51.

Further benefits can be achieved by adding electrical amplification integrated circuits (ICs) to the energy harvesting portion of the system, between the pickup/receiver and the harvesting ICs. This allows the pickup/receiver to act as a sensor, thereby enabling the gathering of information regarding phase relationships, magnitude of current at the source, and the like.

FIGS. 6A-6D illustrate Wireless Transceiver Module 60 associated with a low power, energy harvesting, modular, wireless sensor network node with energy harvesting pickup/receiver.

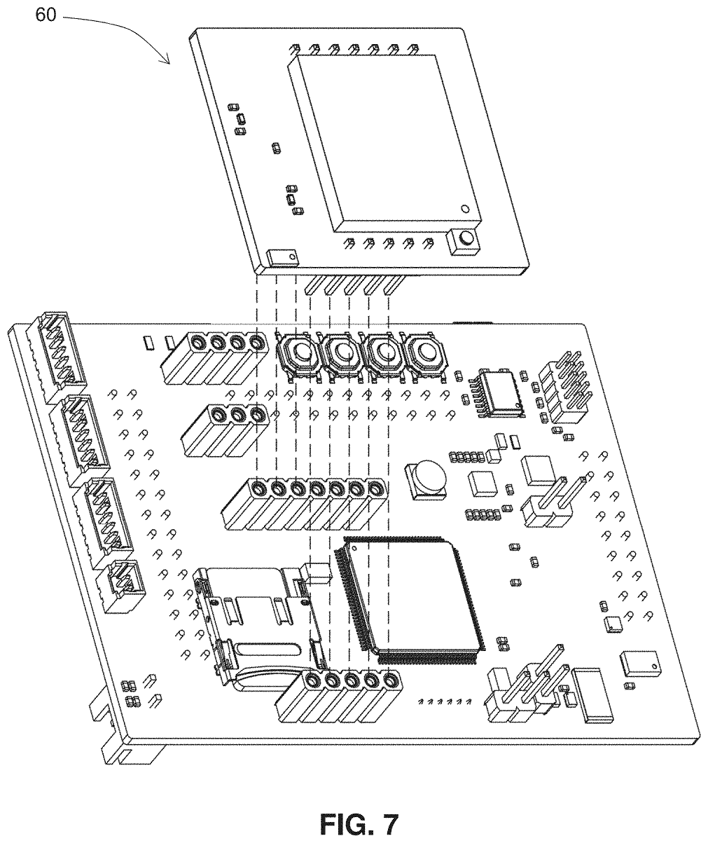

FIG. 7 shows Wireless Transceiver Module 60 being inserted into the printed circuit board for the embodiment of the present low power, energy harvesting, modular, wireless sensor network node with energy harvesting pickup/receiver illustrated in FIGS. 1A-1D.

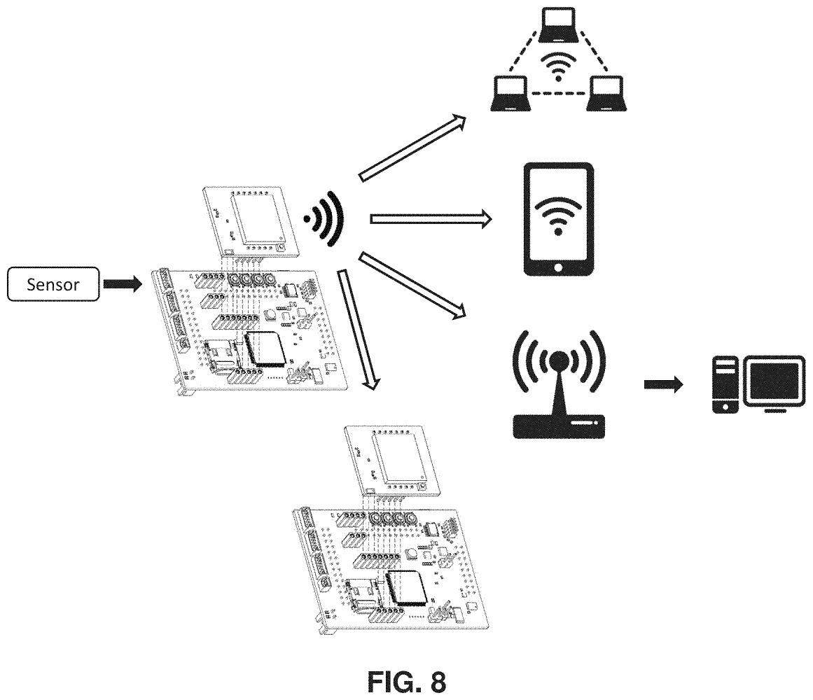

FIG. 8 is a schematic diagram showing the transmission of wireless signals from a Wireless Transceiver Module to one or more of devices capable of receiving the wireless signals including, but not limited to, a computer, tablet/mobile device, gateway, or another system node.

FIG. 9 shows an embodiment of an Energy Storage Device 80 associated a present low power, energy harvesting, modular, wireless sensor network node with energy harvesting pickup/receiver.

FIG. 10 shows Energy Storage Device 80, which is partially shown in FIG. 9.

In some embodiments of the present system, the energy source's conductor can be omitted, so long as the pickup/receiver is within close proximity to an oscillating magnetic field of large enough magnitude.

The pickup/receiver can be tailored to achieve resonance with the energy source in a number of ways, including but not limited to, addition of capacitors, inductors, resistors, and/or other electronic/electrical components. Resonance allows an increase in both magnitude of available energy from the source, as well as an increase in efficiency when that energy is harvested.

In some configurations, the system can be modular, residing entirely on a single PCB. In such modular configurations, the energy harvesting IC can employ one or more of thermoelectric, piezoelectric and solar energy generation methods by swapping out surface-mount resistors.

Modularity provides an economic advantage, namely, by allowing a single reconfigurable PCB to enable several potential end uses/deployments. Modularity reduces or eliminates research and development time and effort to switch between different end uses, thereby allowing the system to implement differing functionalities with minimal added cost.

To improve the robustness of the present system, additional components can be employed, including:
one or more rechargeable batteries (to power the system),
one or more removable memory devices (to save data and configurations on the system itself, and to allow access to the data from another node/device/system/computer),
additional connectors for expanding the system (allowing modularity, future-proofing),
onboard sensors (to satisfy multiple end use requirements),
external USB-type and/or Ethernet connections (for wired communication to enable, for example, system and firmware updates),
one or more electronic switch (to control and switch power to unnecessary electronic parts/subsystems, thereby extending the duration of low-power usage),
a wireless transceiver for transmission and reception of data from/to the system (including but not limited to any one of the following communication protocols: WiFi, Bluetooth, CDMA, 900 MHz, 3G/4G/5G/Cellular), and/or
one or more inductive pickups/receivers (inductively couples with the energy source).

In particular applications of the present device, the low power, energy harvesting, modular, wireless sensor network node and affiliated energy harvesting pickup/receiver can be configured to monitor an electric motor of a machine. In some embodiments, the electrical conductor of the energy harvesting pickup/receiver can be located in close proximity to, or directly connected to the conductor(s) of the motor. In some preferred embodiments, the electrical conductor of the energy harvesting pickup/receiver is coiled around at least one motor phase. In these embodiments, electrical current harvested from the motor by the energy harvesting pickup/receiver can be supplied to the associated circuitry of Energy Harvesting Module 20 and used to power system node 10 and its associated sensors.

In these applications, when Energy Harvesting Module 20 is attached to an electronics processor, it can function as an electrical sensor and the ability of the associated motor, or energy harvesting source, to power the sensor network node serves as a readout of motor function, machine function, and/or energy harvesting source function. In this respect, the energy harvesting ability of the system serves as a sensor for motor, machine, and/or energy harvesting source function.

In some embodiments, artificial intelligence and/or machine learning can be integrated into system node 10 to correlate a specific change in the energy harvesting ability of the system with a motor and/or machine disturbance or malfunction. In these embodiments, different motor malfunctions, which affect the motor winding conditions and therefore change the amount of power delivered to and harvested by system node 10, can be detected as deviations from a baseline energy harvesting capacity of the system. These deviations or energy harvesting signatures can be used to detect and identify a particular motor malfunction.

For example, a particular deviation value or range of values from the baseline energy harvested by system node 10 when powered by a ball bearing motor could indicate a worn, loose, or otherwise compromised ball bearing.

In some embodiments, system node 10 can be configured to shut down a motor when an energy harvesting signature, indicating a motor malfunction, is above a predetermined threshold value. This would allow a motor and its associated machine to be turn off to avoid, or minimize, accumulating localized and/or systemic damage due to continued operation of a compromised motor.

Energy harvesting signature data generated for a motor can be transmitted, logged, and/or monitored in applications and/or software programs on devices such as, but not limited to, mobile phones, tablets, laptops, remote servers, and/or computers. This can allow for off-site monitoring of the function of a motor and its respective machine, or electronic drive.

In some or the same embodiments, the sensors of system node 10 can be simultaneously monitoring motor and/or machine parameters including, but not limited to, vibration, strain, moisture, and/or temperature while monitoring the electric motor winding condition and on/off state. System node 10 can be implemented in printing machinery, canning & packaging machinery, conveyor systems, home appliances such as washing and drying machines, aircrafts, motor vehicles, mills, lathes, grinders, robotic devices, optical feedback systems, rotary devices, and/or other machinery and manufacturing equipment to monitor, at least, vibration and various temperature points from the motor and/or machine. Such monitoring can provide information on the condition and performance of the motor and/or machine as well as its surrounding environment. In some embodiments, sensors can be positioned at various locations on a motor and/or machine to be monitored.

In other applications, the low power, energy harvesting, modular, wireless sensor network node and affiliated energy harvesting pickup/receiver can be mounted to the electric motor/pump assemblies of an oil field to monitor surrounding environmental conditions and/or equipment conditions during use. In some preferred embodiments, system node 10 can detect flooding of motor/pump assemblies. In some embodiments the status of each motor/pump assembly can be monitored off-site via an application and/or software program on devices such as, but not limited to mobile phones, tablets, laptops, remote servers, and/or computers.

In some applications, the low power, energy harvesting, modular, wireless sensor network node and affiliated energy harvesting pickup/receiver can be mounted to a structure such as, but not limited to, a building or bridge to monitor vibration, movement, and/or strain to detect potentially hazardous structural changes and/or surrounding environmental conditions. The status of the structure can be monitored off-site via an application and/or software program on devices such as, but not limited to mobile phones, tablets, laptops, remote servers, and/or computers.

While particular elements, embodiments and applications of the present invention have been shown and described, it will be understood, that the invention is not limited thereto, since modifications can be made by those skilled in the art without departing from the scope of the present disclosure, particularly in light of the foregoing teachings

What is claimed is:

1. A system node comprising:
(a) a printed circuit board comprising an electronic processor;
(b) a sensor module residing on said printed circuit board, said sensor module capable of detecting at least one detectable phenomenon from the surrounding environment and generating electrical signals corresponding to said at least one detectable phenomenon; and
(c) an energy harvesting module comprising an energy harvesting pickup/receiver capable of harvesting electromagnetic energy.

2. The system node of claim 1, wherein said energy harvesting module resides on said printed circuit board.

3. The system node of claim 1, further comprising an energy storage device is attachable to said printed circuit board.

4. The system node of claim 1, further comprising a wireless transceiver module.

5. The system node of claim 1, wherein said detectable phenomenon comprises at least one of light levels, voltage, current, pH, temperature, barometric pressure, material stress, material strain, vibration in time-domain, vibration in frequency domain, humidity, electrical phase relationships, seismic activity, and fluid flow.

6. The system node of claim 1, wherein said detectable phenomenon is generated by a dynamic device.

7. The system node of claim 6, wherein said dynamic device comprises a vehicle, a fluid-carrying pipe, a motor, a structure, or a building having swaying properties.

8. The system node of claim 1, wherein said energy harvesting pickup/receiver is a pickup coil in close proximity to a source of alternating electromagnetic energy.

9. The system node of claim 8, wherein said coil is contoured to said source of alternating electromagnetic energy.

10. The system node of claim 1, wherein said energy harvesting pickup/receiver is a pickup coil in close proximity to a fluctuating magnetic field produced from an outside source.

11. The system node of claim 1, wherein said system node is configured to monitor an electric motor of a machine.

12. The system node of claim 11, wherein an electrical conductor of said energy harvesting pickup/receiver is coiled around at least one conductor of said electric motor.

13. The system node of claim 12, wherein electromagnetic energy in the form of an electrical current is harvested from said electric motor by said energy harvesting pickup/receiver and used to power said system node.

14. The system node of claim 13, wherein said energy harvesting module further comprises an electronics processor, wherein said electronics processor allows said energy harvesting module to function as an electrical sensor.

15. The system node of claim 14, wherein a deviation in an amount of electromagnetic energy delivered to and harvested by said energy harvesting module from said electric motor can be used to detect a mechanical or operational malfunction of said electric motor.

16. The system node of claim 15, further comprising a wireless transceiver module.

17. The system node of claim 16, further comprising an energy storage device is attachable to said printed circuit board.

18. The system node of claim 17, wherein said detectable phenomenon comprises at least one of light levels, voltage, current, pH, temperature, barometric pressure, material stress, material strain, vibration in time-domain, vibration in frequency domain, humidity, electrical phase relationships, seismic activity, and fluid flow.
